(19) United States
(12) Patent Application Publication
(10) Pub. No.: US 2004/0239352 A1
(43) Pub. Date: Dec. 2, 2004

(54) Probe card used for inspecting semiconductor devices

(75) Inventor: Osamu Mizoguchi, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 10/853,265

(22) Filed: May 26, 2004

(30) Foreign Application Priority Data
May 26, 2003 (JP) 2003-147783

(51) Int. Cl. G01R 31/02

(52) U.S. Cl. 324/754

(57) ABSTRACT

A probe card and a method of inspecting semiconductor devices, capable of reducing necessity of a means for cleaning a probe, and of improving throughput of the inspection, are provided, in which a contact portion to be brought into contact with an electrode pad and a cutting edge portion are provided side by side at the end portion of the probe, and the measurement is carried out under overdrive, so as to allow the cutting edge portion to scrub any oxide film or foreign matters off from the surface of the electrode pad, to thereby allow the contact portion to contact with the refreshed surface of the electrode pad.

This application is based on Japanese patent application No.2003-147783, the content of which is incorporated hereinto by reference.

### FIELD OF THE INVENTION

The present invention relates to a probe card used for inspecting semiconductor devices.

### BACKGROUND OF THE INVENTION

It is general practice to provide an inspection step of measuring electric characteristics of a plurality of semiconductor devices formed on a semiconductor wafer (simply referred to as “wafer”, hereinafter), and or sorting these semiconductor devices. An inspection device used therefor comprises a probing unit having a probe card with probes which are brought into contact with a plurality of electrode pads disposed on the semiconductor devices formed on the wafer placed on a stage, and a main unit of tester for measuring the electric characteristics of the semiconductor device based on signal sending-and-receiving to or from the probes.

How stably the contact between the electrode pads and probes can be ensured and how reliably the inspection can be carried out have been understood as critical subjects for the inspection device. Hence various methods have been proposed in pursuit of obtaining the stable contact.

One exemplary method presses the probes to a cleaning sheet for cleaning these probes every time the probes are brought into contact with the electrode pads, to thereby remove any foreign matters adhered to the probes. The method is successful in removing the foreign matters adhered to the end portion of the probes with the aid of the cleaning sheet, but unsuccessful in thoroughly removing those adhered to the side faces of the probes. In some cases, a higher frequency of the cleaning may undesirably promote wear of the probes and thereby shorten the service life. It is to be noted that the term of “foreign matters” in this specification also means a metal dust removed from an electrode pad of a semiconductor device under measurement.

FIGS. 1 and 2 are drawing for explaining an exemplary conventional method of inspecting semiconductor devices disclosed in Japanese Laid-Open Patent Publication No. 2002-319605 (on pages 4-5, FIGS. 1 and 2). In this sort of conventional method of inspecting semiconductor devices, the foreign matters adhered to a probe 22 is removed by allowing it to contact with a cleaning sheet 27 shown in FIG. 1, after a plurality of semiconductor devices were inspected.

The cleaning sheet 27 shown in FIG. 1 is configured so that an abrasive grain layer 25 is disposed on a first cushion material 23 while placing a tacking material 24 in between, and further thereon a second cushion material 26 is adhered. The probe 22 is cleaned by sticking it into the second cushion material 26 and making it contact with the abrasive material layer 25, to thereby scrub the end portion 22a of the probe 22 and to concomitantly remove foreign matters 28 adhered to the end portion 22a and side faces 22b of the probe 22.

The probe 22 having the foreign matters removed therefrom has been used for inspection, as shown in FIG. 2, by making contact of a portion thereof to be brought into contact, that is, the acute-angled spherical end portion 22a, with an Au bump electrode 21 formed on a semiconductor device 20. The aforementioned publication describes that the acute-angled spherical shape of the end portion 22a of the probe 22 is advantageous in reducing wear and elongating the service life of the probe, because the contact can be established without needing an amount of overdrive (amount of pressurizing of the end portion of the probe into the electrode).

The aforementioned publication also describes that absence of the overdrive into the Au bump electrode 21 is advantageous enough to suppress scaling-off of the upper surficial portion of the Au bump electrode 21 and to thereby reduce adhesion of foreign matters to the probe 22.

Another probe card is disclosed in Japanese Laid-Open Patent Publication No. 9-304433, especially in FIG. 2 and FIG. 3. The probe card of this prior art includes a probe having two tips comprised of a main tip and a sub tip in order to increase an area contacting a pad of a semiconductor chip. The sub tip reduces pressure to face in the probe, so that reduce wear of the probe.

Yet another probe card is disclosed in Japanese Laid-Open Patent Publication No. 6-174744. This probe card of this prior art also includes a probe having two tips. One of the two tips is forced on a pad of a semiconductor chip by another and in electrical contact with the pad.

We have now discovered that it is highly necessary for the above-described method of inspecting semiconductor devices to use the cleaning sheet for cleaning the probe, and this consequently raises a large need of aligning the probe to the cleaning sheet. These operations make it difficult to improve throughput of the inspection.

We have also discovered that it is still difficult to thoroughly remove the foreign matters from the probe even if the probe is brought into contact with the cleaning sheet. Even if the removal should be successful, the foreign matters remained in the cleaning sheet may re-adhere to the probe when the probe is brought into contact with the cleaning sheet again.

### SUMMARY OF THE INVENTION

The present invention is to provide a probe card used for inspecting semiconductor devices, comprising a plurality of probes, each of which has a first tip and a second tip. And the first tip is different in shape from said second tip such that the first tip scrubs a surface of a pad of a semiconductor chip and the second tip is in electrical contact with the pad.

According to these configurations, by sliding the cutting edge portion and contact portion of the probe for the measurement, it is made possible for the contact portion to always make contact with the refreshed surface of a portion to be measured from which any oxide film and foreign matters have been removed by the cutting edge portion, and this ensures an effect of enabling a highly reliable inspection.

While configurations of the present invention were described in the above, it is to be understood that any arbitrary combinations of these configurations are effective as the embodiment of the present invention.

Although the cutting edge portion and the contact portion may be provided in an one-by-one relation; other possible relations include that the cutting portion is provided in plural number with respect to a single contact portion, and that a single cutting edge portion is provided with respect to a plurality of contact portions.

### BRIEF DESCRIPTION OF THE DRAWINGS

FIG. 1 is a drawing for explaining a conventional method of inspecting semiconductor devices.

FIG. 2 is a drawing for explaining a conventional method of inspecting semiconductor devices.

FIG. 3 is a drawing showing a partial sectional view of a probe card of one embodiment of the present invention, and enlarged views of portion “A”.

FIG. 4 is a partial sectional view showing one modified example of the probe card shown in FIG. 3.

FIGS. 5A and 5B are drawings showing a part of the probe for explaining another modified example of the probe card shown in FIG. 3.

FIGS. 6A and 6B are a plan view and a sectional view taken along line A-A for explaining a method of inspecting semiconductor devices according to one embodiment of the present invention.

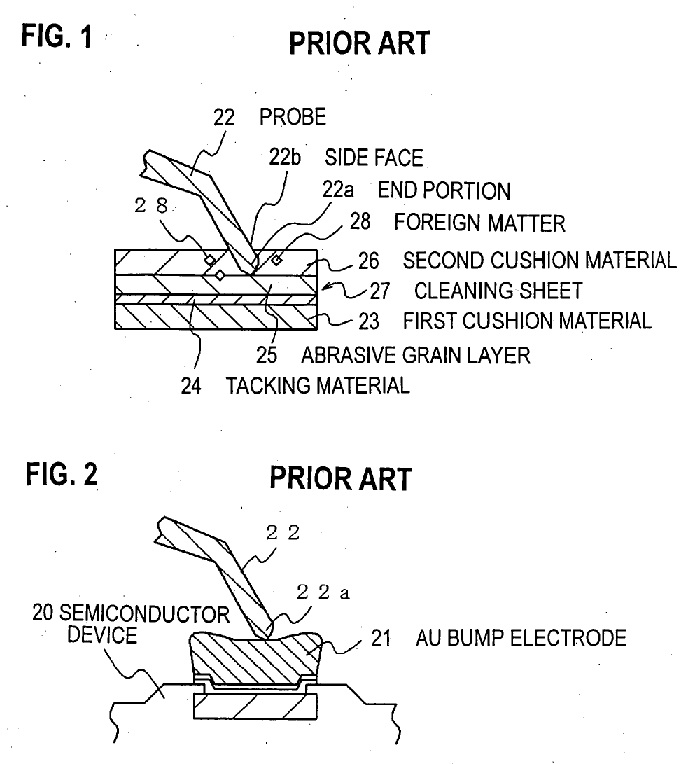

### DETAILED DESCRIPTION OF THE INVENTION

The following paragraphs will describe embodiments of the present invention referring to the attached drawings. It is to be noted that any similar constituents will have the same reference numerals, and explanations therefor will properly be omitted.

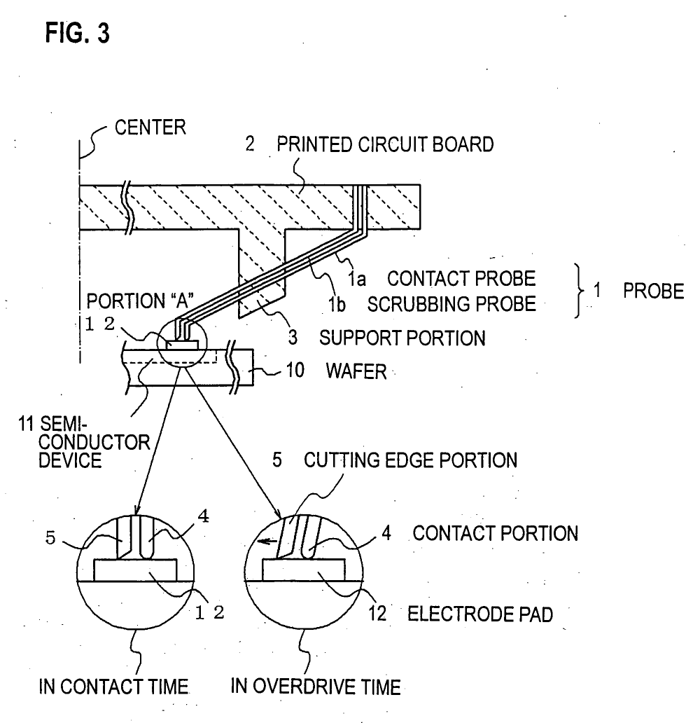

FIG. 3 shows a partial sectional view of a probe card according to one embodiment of the present invention, and enlarged views of portion “A”. As shown in FIG. 3, the probe card comprises a printed wiring board 2 connected to wirings which take part in sending-and-receiving of signals to and from a main unit of a tester (not shown); and a plurality of probes 1 extending out from the circumferential portion of the printed wiring board 2 obliquely downward, bent near-vertically, and brought into contact with an electrode pad 12 of a semiconductor device 11 formed on a wafer 10 so as to effect sending-and-receiving of signals therewith, wherein a cutting edge portion 5 for scrubbing the surface of the electrode pad 12 and a contact portion 4 brought into contact with the surface of the electrode pad 12 are formed side by side at the end portion of each probe so as to align them towards the center of the semiconductor device 11.

The cutting edge portion 5 and the contact portion 4 are independently provided to a scrubbing probe 1b and a contact probe 1a, both of which extending out from the printed wiring board 2. The scrubbing probe 1b having the cutting edge portion 5 is preferably fabricated using tungsten (W), or rhenium-tungsten which is a tungsten alloy. The scrubbing probe 1b composed of a material containing tungsten, or an alloy of tungsten and rhenium is characterized by its excellent hardness and wear-proof property, and can efficiently scrub any oxide film or foreign matters off from the surface of the electrode pad 12. The scrubbing probe 1b composed of this sort of material with high abrasion resistance such as tungsten alloy is also excellent in durability or reliability. On the other hand, the contact probe la having the contact portion 4 is preferably fabricated using beryllium-copper (BeCu) excellent in electric conductivity and spring property. The contact probe la composed of this sort of material is excellent in contact property with the electrode pad 12, and also in durability or reliability.

It is to be noted that both of the scrubbing probe 1b and contact probe 1a may be connected to a land of the printed wiring board 2. The plurality of probes 1 are fixed to a support portion 3 projected downwardly from the printed wiring board 2, so as to attain a cantilever structure. It is designed so as to avoid direct force application to the joint portion between the probe 1 and printed wiring board 2 during overdrive shown in the right circle of the drawing.

The probe card is configured so that both of the contact probe 1a and the scrubbing probe 1b are brought into contact with the electrode pad 12 at the contact portion 4 and the cutting edge portion 5, respectively, which reside on their end portions, and so that, during the overdrive, the cutting edge portion 5 is slid on the surface of the electrode pad 12 so as to remove any oxide film or foreign matters on the surface of the electrode pad 12, and the contact portion 4 is pressed into the surficial portion of the electrode pad 12 having the foreign matters and oxide film already removed therefrom so as to attain a desirable electric contact. The cutting edge portion 5 has an acute-angled tip, and the contact portion 4 has a spherical tip.

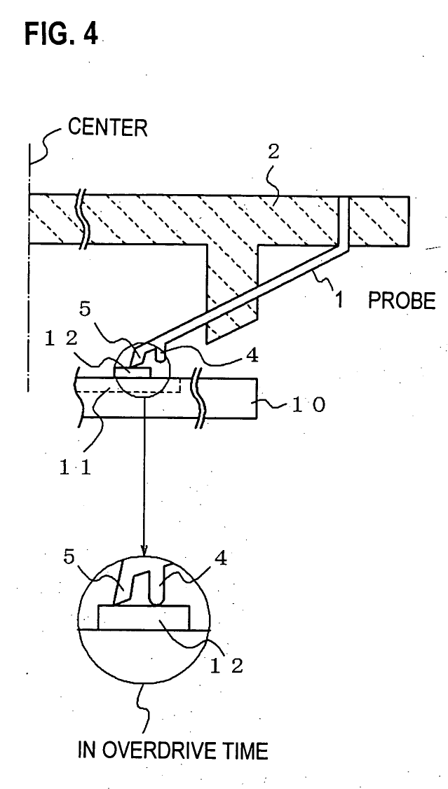

FIG. 4 is a partial sectional view showing one modified example of the probe card shown in FIG. 3. As shown in FIG. 4, the prove card has the probe 1 extended from the printed wiring board 2, at the end portion of which the cutting edge portion 5 and the contact portion 4 are provided side by side as being aligned towards the center of the semiconductor device.

It is also allowable to fabricate the probe 1 and the cutting edge portion 5 in an integrated manner using a rhenium-tungsten material and to attach thereto the contact portion 4, made of a beryllium-copper material, typically by brazing; or to fabricate the probe 1 and the contact portion 4 in an integrated manner using a beryllium-copper material and to attach thereto the cutting edge portion 5, made of a rhenium-tungsten material, typically by butt welding in which a filler typically composed of a cobalt material is fused by laser or electron beam irradiation. The latter is better considering spring property and electric conductivity required for the probe 1, and hardness required for the cutting edge portion 5.

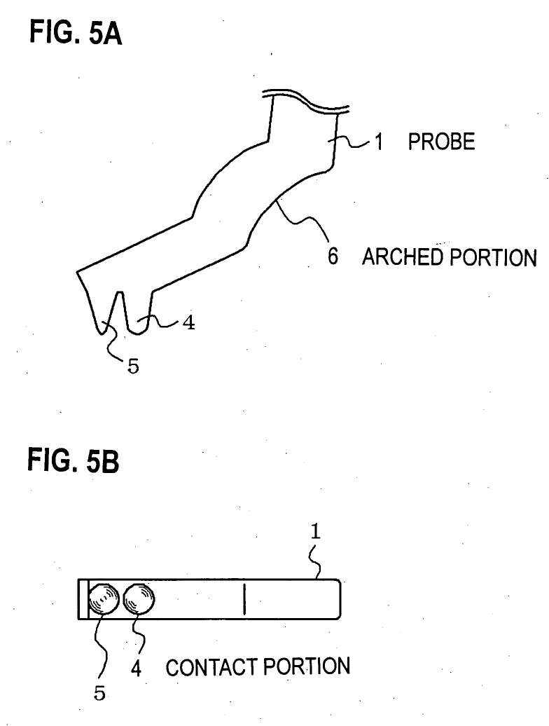

FIGS. 5A and 5B are drawings for explaining still another modified example of the probe card shown in FIG. 3. The probe card is, as shown in FIG. 5A, fabricated so as to integrate the probe 1 and the contact portion 4 at the end portion thereof, and so as to attach the cutting edge portion 5 in adjacent to the contact portion 4.

The probe 1 and the contact portion 4 are preferably composed of beryllium-copper, for example, which is excellent in spring property and electric conductivity. The cutting edge portion 5 is preferably fabricated by first forming a tungsten-sputtered film on the flat surface of the end portion of the probe 1, then by forming thereon a projected portion composed of a tungsten crystal by the vapor-phase epitaxial growth process, and by processing the projected portion by ion milling so as to obtain an cutting edge, in place of using a general tungsten sintered alloy. It is preferable to provide an arched portion 6 to the probe 1 so as to ensure linear sliding of the end portion of the probe 1.

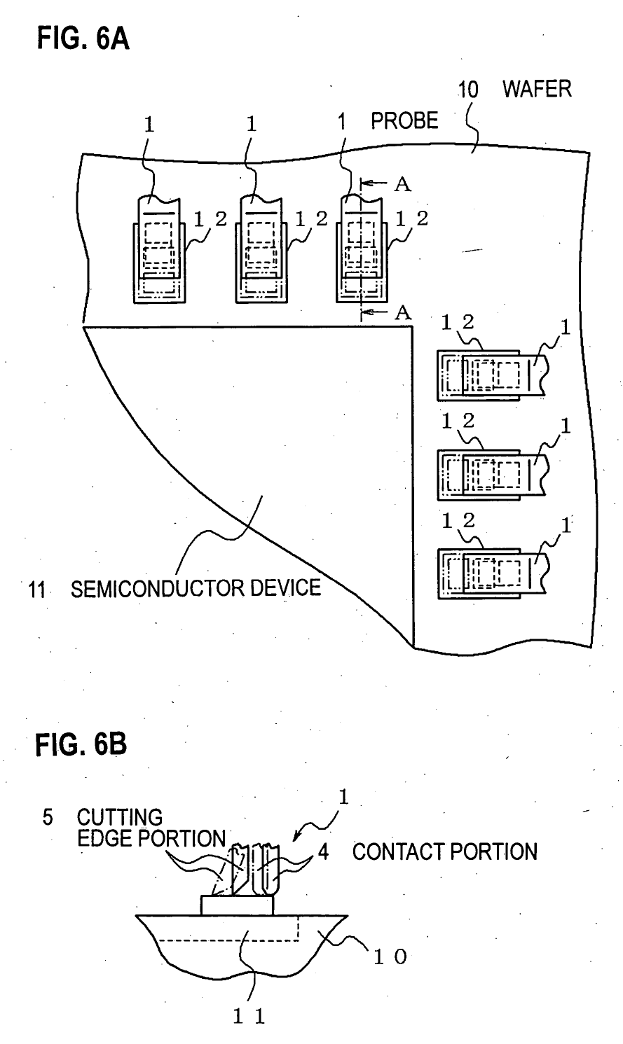

FIGS. 6A and 6B are a plan view and a sectional view taken along line A-A, respectively, for explaining a method of inspecting semiconductor devices according to one embodiment of the present invention. In the method of inspecting semiconductor devices, a stage (not shown) having the wafer 10 shown in FIG. 6A placed thereon is elevated to thereby bring the end portion of the probe 1 into contact with the electrode pad 12. In this state, the end portion of the probe 1 is indicated by solid lines in FIG. 6A.

The stage is then further elevated from the state where the end portion of the probe 1 is brought into contact with the electrode pad 12, so as to effect the overdrive. This allows the end portion of the probe 1 to slide in the direction towards the center of the semiconductor device 11. In an exemplary case shown in FIGS. 4A and 4B, the end portion of the probe 1 slides to reach a position indicated by the two-dot chain line. As a consequence, the cutting edge portion 5 successfully removes an oxide film on the electrode pad 12, so as to allow the contact portion 4 to contact with the refreshed surface for exact signal sending-and-receiving. It is to be noted that adhesion of a removed oxide film to the cutting edge portion 5 is less causative of degraded reliability in the signal sending-and-receiving because the cutting edge portion 5 does not contribute to electric contact. The contact of the contact portion 4 always with the refreshed surface can ensure a stable electric contact.

A length of sliding should be determined by the size of the electrode pad and the distance between the cutting edge portion and the contact portion. That is, the length of sliding should be smaller than the size of the electrode pad in order to keep the semiconductor device free from being damaged by the cutting edge portion. Furthermore, the length of sliding should be larger than the distance between the cutting edge portion and the contact portion so as to allow the contact portion to electrically contact with refreshed surface of the electrode pad.

From another point of view, a probe card can be summarized as having a printed wiring board connected to wirings which take part in sending-and-receiving of signals to and from a main unit of a tester, and a plurality of probes extending out from the circumferential portion of the printed wiring board obliquely downward and being bent near-vertically, each of which having an end portion brought into contact with an electrode of a semiconductor device formed on a wafer, being provided for the sending-and-receiving of signals; wherein a cutting edge portion for scrubbing the surface of the electrode pad and a contact portion brought into contact with the surface of the electrode pad are formed side by side at the end portion of the probe as being aligned towards the center of the semiconductor device.

The cutting edge portion and the contact portion are preferably provided independently from each other to the probe extending out from the printed wiring board, or to the same probe. It is also preferable that the cutting edge portion is fabricated by growing a high-hardness refractory metal by the vapor-phase epitaxy process. On the other hand, the cutting edge portion preferably contains an alloy of tungsten and rhenium; and that the contact portion contains a copper alloy mainly composed of copper.

From another point of view, the method of inspecting the semiconductor devices using the probe card of the present embodiment can be summarized as using a probe card, where the probe card comprising a printed wiring board connected to wirings which take part in sending-and-receiving of signals to and from a main unit of a tester; and a plurality of probes extending out from the circumferential portion of the printed wiring board obliquely downward, bent near-vertically, and brought into contact with an electrode pad of a semiconductor device formed on a wafer so as to effect sending-and-receiving of signals therewith, wherein a cutting edge portion for scrubbing the surface of the electrode pad and a contact portion brought into contact with the surface of the electrode pad are formed side by side at the end portion of each probe so as to align them towards the center of the semiconductor device, wherein a relative distance between the wafer and the probe card is shrunk so as to finally bring the end portion of the probe and the electrode pad into contact, and sliding of the end portion of the probe on the surface of the electrode pad is induced by increasing the amount of pressurizing of the end portion of the probe against the electrode pad.

The amount of sliding of the end portion of the probe on the surface of the electrode pad is 10 μm to 20 μm, both ends inclusive.

According to the configurations explained in the above, by providing the cutting edge portion at the end portion of the probe in adjacent to the contact portion to be brought into contact with the electrode pad, and by effecting the overdrive during the measurement, it is made possible for the contact portion to always make contact with the refreshed surface of a portion to be measured from which any oxide film and foreign matters have been removed by the cutting edge portion, and this ensures an effect of enabling a stable measurement and a highly reliable inspection.

The configuration is also advantageous in raising the throughput because it is not need to clean the probe after every contact. Additionally, it is not need to provide a separate mechanism for cleaning the probe.

While configurations of the present invention were described in the above, it is to be understood that any arbitrary combination of these configurations is effective as an embodiment of the present invention. It is to be understood that any expression of the present invention converted into some other category is effective as an embodiment of the present invention.

The electrode pad was typically used as the portion to be measured of the semiconductor device, while being not specifically limited thereto. For example, the portion to be measured may be any exposed portions of wirings provided to semiconductor devices, or may be any exposed portions of electro-conductive components such as capacitor, transistor and fuse.

The method of allowing the probe to slide on the surface of the electrode pad was typically a method of pressing the probe into the surficial portion of the electrode pad, while being not specifically limited thereto. For example, it is also allowable to laterally move the entire portion of the probe using a mechanical device such as motor, to thereby allow the probe to slide on the surface of the electrode pad.

From another point of view, the present invention is to provide a probe used for inspecting semiconductor devices, comprising a cutting edge portion having an acute-angled tip; and a contact portion having a spherical tip. The present invention is also to provide a probe card, and an inspection device incorporating thus-configured probe.

According to these configurations, by sliding the cutting edge portion and contact portion of the probe for the measurement, it is made possible for the contact portion to always make contact with the refreshed surface of a portion to be measured from which any oxide film and foreign matters have been removed by the cutting edge portion, and this ensures an effect of enabling a highly reliable inspection.

The present invention is still also to provide a method of inspecting semiconductor devices, which comprises making a cutting edge portion, having an acute-angled tip, and a contact portion, having a spherical tip, of a probe contact with a surface of a portion to be measured of the semiconductor device; sliding the cutting edge portion and the contact portion of the probe in the direction of disposition of the cutting edge portion as viewed from the contact portion on the surface of the portion to be measured of the semiconductor device; and sending and receiving electric signals between the contact portion of the probe and the surface of the portion to be measured of the semiconductor device.

According to this method, by sliding the cutting edge portion and contact portion of the probe for the measurement, it is made possible for the contact portion to always make contact with the refreshed surface of a portion to be measured from which any oxide film and foreign matters have been removed by the cutting edge portion, and this ensures an effect of enabling a highly reliable inspection.

It is apparent that the present invention is not limited to the above embodiments, but may be modified and changed without departure from the scope and spirit of the invention.

What is claimed is:

1. A probe card comprising:
a plurality of probes, each of which has a first tip and a second tip;
wherein said first tip is different in shape from said second tip such that said first tip scrubs a surface of a pad of a semiconductor chip and said second tip is in electrical contact with said pad.

2. The probe card as claimed in claim 1, wherein:
said first tip has an edge-like shape and said second tip has a round shape.

3. The probe card as claimed in claim 1, wherein:
said first tip is made of a material with higher abrasion resistance than said second tip, and said second tip is made of a material with higher electrical conductivity than said first tip.

4. The probe card as claimed in claim 1, wherein:
each of said plurality of probes has a first rod and a second rod, and said first tip is formed on said first rod and said second tip is formed on said second rod.

5. The probe card as claimed in claim 4, wherein:
said first tip and said first rod are made of a material with higher abrasion resistance than said second tip, and said second tip and said second rod are made of a material with higher electrical conductivity than said first tip.

6. The probe card as claimed in claim 1, wherein
each of said plurality of probes has a rod, and said first tip and said second tip are formed on said rod.

7. The probe card as claimed in claim 6, wherein:
said first tip is made of a material with higher abrasion resistance than said second tip, and said second tip and said rod are made of a material with higher electrical conductivity than said first tip.

8. The probe card as claimed in claim 1, further comprising:
a board, to which said plurality of probes are connected;
wherein said first tip and said second tip of each of said plurality of probes are arranged in line toward a center of said board.

9. The probe card as claimed in claim 8, wherein:
said first tip is near said center from said second tip.

10. The probe card as claimed in claim 1, wherein
said first tip and said second tip of each of said plurality of probes are arranged in line toward a center of said semiconductor device.

11. The probe card as claimed in claim 10, wherein
said first tip is near said center from said second tip.

12. The probe card as claimed in claim 3, wherein said material with higher abrasion resistance contains tungsten of an alloy of tungsten and rhenium, and said material with higher electrical conductivity contains copper.

13. The probe card as claimed in claim 5, wherein said material with higher abrasion resistance contains tungsten of an alloy of tungsten and rhenium, and said material with higher electrical conductivity contains copper.

14. The probe card as claimed in claim 7, wherein said material with higher abrasion resistance contains tungsten of an alloy of tungsten and rhenium, and said material with higher electrical conductivity contains copper.
